(19) United States
(12) Patent Application Publication
(10) Pub. No.: US 2026/0113861 A1
(43) Pub. Date: Apr. 23, 2026

(54) TRANSMISSION MECHANISM, ADAPTER MODULE AND DATA PROCESSING DEVICE

(71) Applicant: Wiwynn Corporation, New Taipei City (TW)

(72) Inventors: Ping-Sheng Yeh, New Taipei City (TW); Lai-Wang Cai, New Taipei City (TW)

(73) Assignee: Wiwynn Corporation, New Taipei City (TW)

(21) Appl. No.: 18/966,159

(22) Filed: Dec. 3, 2024

(30) Foreign Application Priority Data
Oct. 17, 2024 (TW) 113139460

(51) Int. Cl. H05K 7/14

(52) U.S. Cl. CPC H05K 7/1489; H05K 7/1452

(57) ABSTRACT

A transmission mechanism includes a first sliding rod, a second sliding rod, a cross rod and at least one power clip. The second sliding rod is parallel to the first sliding rod. An end of the cross rod is connected to the first sliding rod, and another end of the cross rod is connected to the second sliding rod. The at least one power clip is fixed to the cross rod. The transmission mechanism may be applied to an adapter module and a data processing device to make the disassembly and assembly of an electronic component and a rack faster and more convenient.

### BACKGROUND OF THE INVENTION

### 1. Field of the Invention

The invention relates to a transmission mechanism and, more particularly, to a transmission mechanism capable of being applied to an adapter module and a data processing device.

### 2. Description of the Prior Art

At present, a server rack may accommodate a plurality of chassis, which are also known as trays or sleds, and each chassis is configured to carry computing circuits of a server. In a multi-system serial-connected architecture, a plurality of power supplies corresponding to a plurality of computing circuits are integrated into one power module, and the power module may be connected in series between a plurality of chassis and a power busbar. The server may be connected to the busbar behind the rack through a rear power module (RPM). If there is no aisle behind the rack, during assembly, a user needs to first connect the rear power module to the busbar and then connect the server to the rear power module. During disassembly, the user needs to first disconnect the server from the rear power module and then disconnect the rear power module from the busbar. However, the more connectors the rear power module comprises, the larger the overall mating force needs to be overcome. As a result, it is very laborious to assemble the rear power module with the busbar or disassemble the rear power module from the busbar.

### SUMMARY OF THE INVENTION

Therefore, an objective of the invention is to provide a transmission mechanism, an adapter module and a data processing device configured to assist in overcoming the mating force between connectors.

According to an embodiment of the invention, a transmission mechanism comprises a first sliding rod, a second sliding rod, a cross rod and at least one power clip. The second sliding rod is parallel to the first sliding rod. An end of the cross rod is connected to the first sliding rod, and another end of the cross rod is connected to the second sliding rod. The at least one power clip is fixed to the cross rod.

According to an embodiment of the invention, an adapter module comprises a drawer, the aforesaid transmission mechanism, a bracket, at least one connector and a cable cartridge. The transmission mechanism is movably disposed at a rear side of the drawer. The first sliding rod and the second sliding rod extend outside of a front side of the drawer. The bracket is disposed at the front side of the drawer. The at least one connector is disposed on the bracket. The at least one connector is connected to the at least one power clip. The cable cartridge is disposed at the front side of the drawer.

According to an embodiment of the invention, a data processing device comprises a rack, the aforesaid adapter module and an electronic component. The rack comprises a sliding rail and a busbar. The adapter module is disposed in the rack and adjacent to the busbar. When the electronic component is being pushed into the rack along the sliding rail, the electronic component pushes the first sliding rod and the second sliding rod to drive the transmission mechanism moving toward the busbar, such that the electronic component is connected to the at least one connector and the cable cartridge, and the at least one power clip is connected to the busbar.

The transmission mechanism, the adapter module and the data processing device of the invention have the following characteristics: 1) the transmission mechanism can transfer a pushing force from a user to the power clip to assist in overcoming a mating force of the power clip into the busbar; 2) a separator of the transmission mechanism can store an elastic force to assist in overcoming an unmating force of the power clip from the busbar, such that the user may spend less pulling force; and 3) a support frame of the transmission mechanism is made of elastic metal material, which can buffer at least one of a part of the mating force, the pushing force and the pulling force to prevent the cross rod of the transmission mechanism from breaking. Therefore, through the arrangement of the transmission mechanism of the invention, the disassembly and assembly of the electronic component and the rack can be faster and more convenient.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is an isometric view illustrating a transmission mechanism according to an embodiment of the invention.

FIG. 2 is an isometric view illustrating the transmission mechanism shown in FIG. 1 from another viewing angle.

FIG. 3 is an exploded view illustrating the transmission mechanism 3 shown in FIG. 1.

FIG. 4 is an isometric view illustrating an adapter module according to an embodiment of the invention.

FIG. 5 is an exploded view illustrating the adapter module shown in FIG. 4.

FIG. 6 is a partial inside view illustrating the adapter module shown in FIG. 4.

FIG. 7 is an isometric view illustrating a data processing device according to an embodiment of the invention.

FIG. 8 is an isometric view illustrating the data processing device shown in FIG. 7 from another viewing angle.

FIG. 9 is a partial isometric view illustrating the electronic component, the handle and the sliding rail from another viewing angle.

FIG. 10 is a top view illustrating the handle of the electronic component shown in FIG. 7 staying at an opened position.

FIG. 11 is a top view illustrating the handle of the electronic component shown in FIG. 7 staying at a closed position.

### DETAILED DESCRIPTION

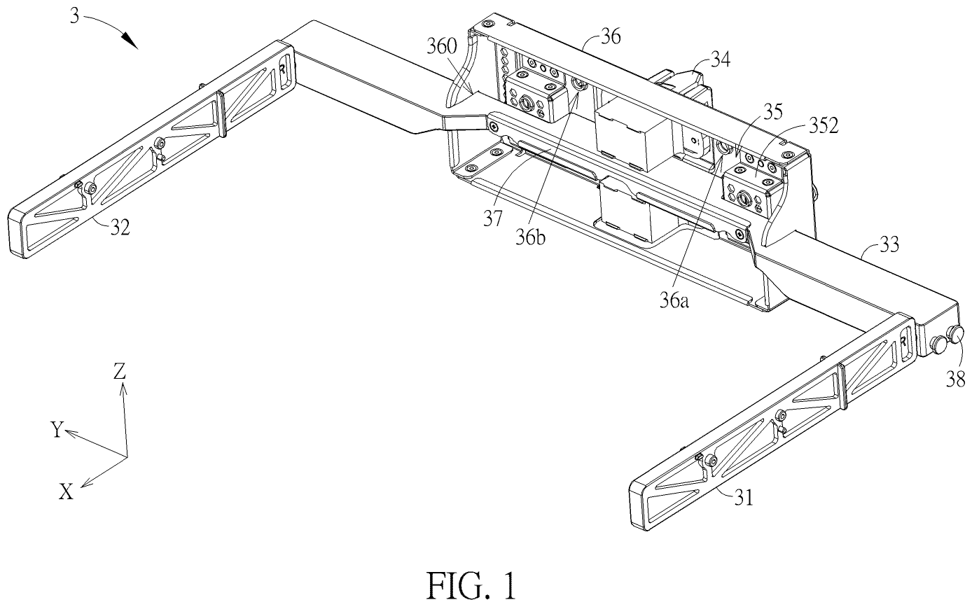

Referring to FIG. 1, which is an isometric view illustrating a transmission mechanism 3 according to an embodiment of the invention. The transmission mechanism 3 comprises a first sliding rod 31, a second sliding rod 32, a cross rod 33, at least one power clip 34, a plurality of separators 35, a casing 36 and a support frame 37.

Structurally, the second sliding rod 32 is parallel to the first sliding rod 31. An end of the cross rod 33 is connected to the first sliding rod 31, and another end of the cross rod 33 is connected to the second sliding rod 32, such that the first sliding rod 31, the second sliding rod 32 and the cross rod 33 are U-shaped. The first sliding rod 31 and the second sliding rod 32 may extend along a first direction X, the cross rod 33 may extend along a second direction Y, the at least one power clip 34 may be arranged along a third direction Z, wherein the first direction X, the second direction Y and the third direction Z are perpendicular to each other.

The at least one power clip 34 is fixed to the cross rod 33. In this embodiment, the transmission mechanism 3 may comprise two power clips 34 respectively fixed to opposite sides of the cross rod 33. The number and position of power clips 34 may be determined according to practical applications. In this embodiment, the power clip 34 may be, for example, a busbar clip connector.

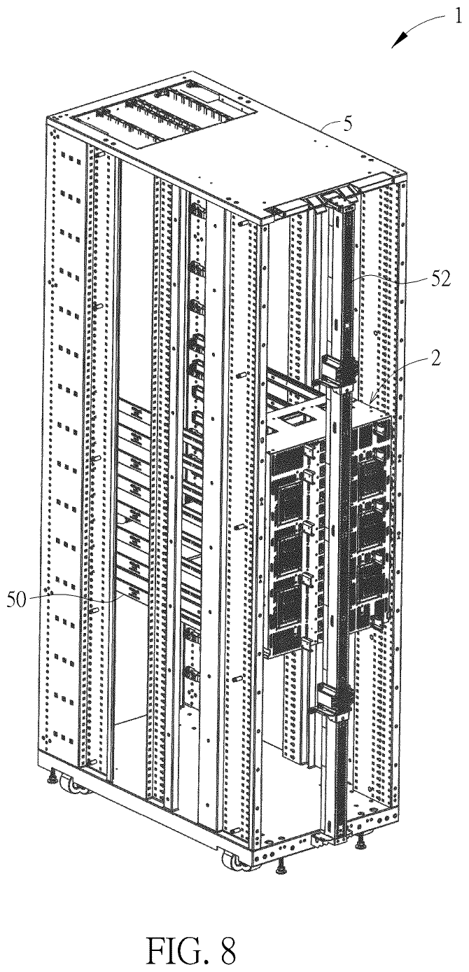

The separators 35 are fixed to the cross rod 33 and disposed at two sides of the at least one power clip 34, wherein the separators 35 are configured to provide a force for separating the at least one power clip 34. The separators 35 disposed at two sides of the at least one power clip 34 may provide balanced force to assist in separating the power clip 34 from a busbar 52 (as shown in FIG. 8). In this embodiment, the transmission mechanism 3 may comprise two separators 35. The number and position of separators 35 may be determined according to practical applications.

The casing 36 is fixed to the cross rod 33, and the at least one power clip 34 and the separators 35 are fixed to the casing 36. In other words, the at least one power clip 34 and the separators 35 may be fixed to the cross rod 33 through the casing 36. For example, the at least one power clip 34 and the separators 35 may be fixed to the casing 36 by screws and washers, and the casing 36 may be fixed to the cross rod 33 by screws, such that the at least one power clip 34 and the separators 35 are fixed to the cross rod 33. In this embodiment, two sides of the casing 36 may be formed with two engaging recesses 360. The cross rod 33 may engage with the two engaging recesses 360, such that the casing 36 is fixed to the cross rod 33. In this embodiment, a cover 352 of each separator 35 may be fixed to the casing 36.

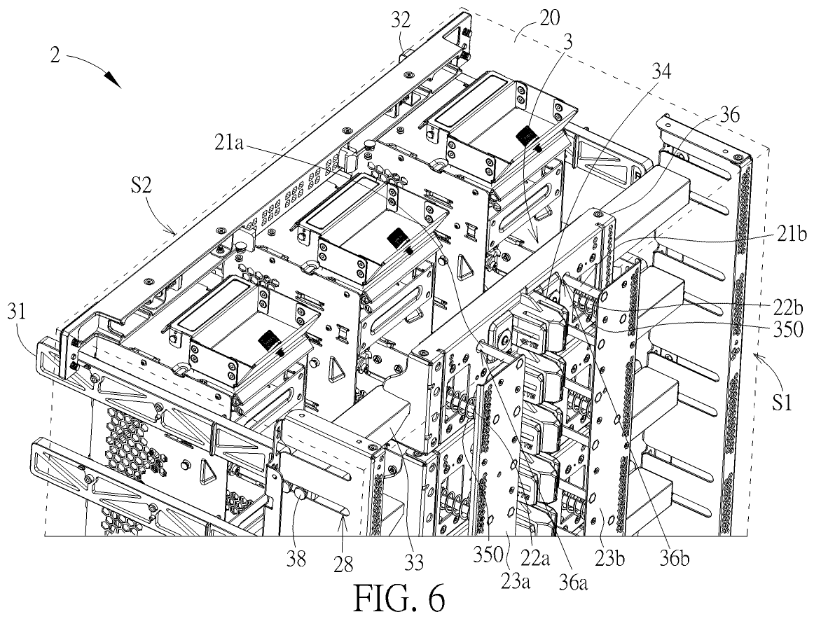

The casing 36 is formed with a hole 36a corresponding to a first guiding pin 21a (as shown in FIG. 6) of a drawer 20. The hole 36a is configured to restrain the transmission mechanism 3 locating on the first guiding pin 21a, so as to align the power clip 34 with the busbar 52 (as shown in FIG. 8). In this embodiment, the casing 16 is formed with one pair of holes 36a, 36b located at two sides of one power clip 34 and respectively corresponding to one pair of first guiding pins 21a, 21b (as shown in FIG. 6) of the drawer 20. In other embodiments, the numbers of holes and first guiding pins may be determined according to practical applications.

The support frame 37 is fixed to the cross rod 33 and configured to support the cross rod 33, so as to enhance the overall structural strength of the transmission mechanism 3. It should be noted that in order to transfer the pushing or pulling force spent by a user on the first sliding rod 31 and the second sliding rod 32 to the cross rod 33, and meanwhile prevent the mating force between the power clip 34 and the busbar 52 from breaking the cross rod 33, a stiffness of the cross rod 33 is larger than a stiffness of the support frame 37. That is to say, an elasticity of the cross rod 33 is less than an elasticity of the support frame 37. In this embodiment, the cross rod 33 is made of non-metal material and the support frame is made of elastic metal material. Since the support frame 37 is elastic, the support frame 37 can buffer at least one of a part of the mating force, pushing force and pulling force to prevent the cross rod 33 from breaking.

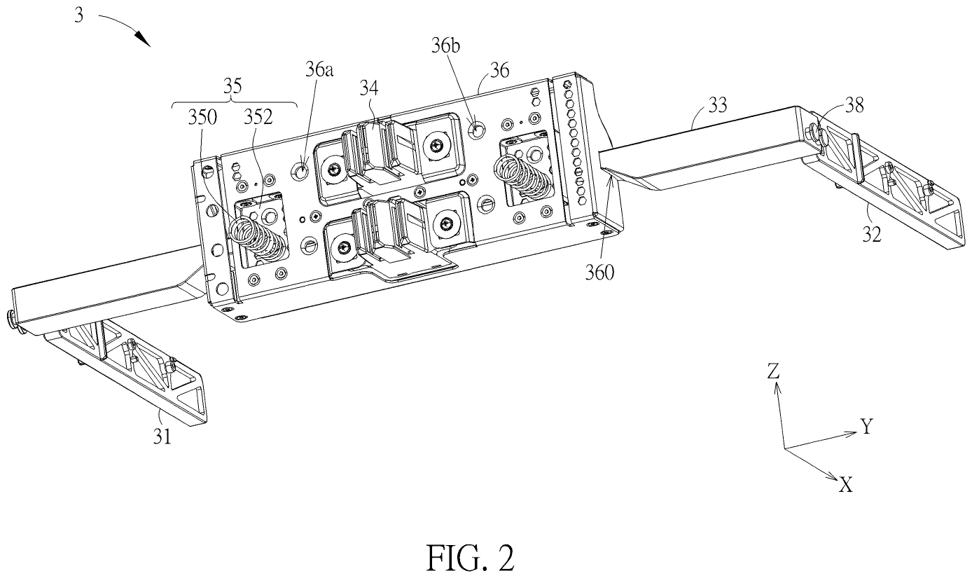

FIG. 2 is an isometric view illustrating the transmission mechanism 3 shown in FIG. 1 from another viewing angle. Each of the separators 35 comprises an elastic member 350 and a cover 352, wherein an end of the elastic member 350 abuts against the cover 352. The elastic member 350 may be a spring or a stamped elastic sheet. During assembly, the power clip 34 is inserted into the busbar 52 and the elastic member 350 is compressed to store an elastic force. During disassembly, the elastic force stored by the elastic member 350 may assist in separating the power clip 34 from the busbar 52.

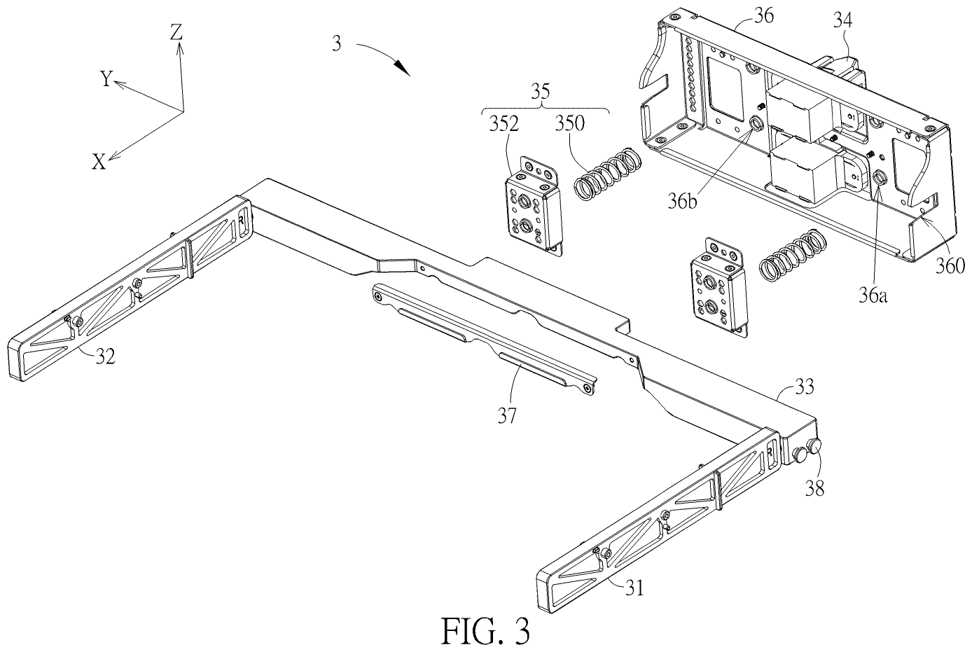

FIG. 3 is an exploded view illustrating the transmission mechanism 3 shown in FIG. 1. All in all, the transmission mechanism 3 can transfer a pushing force of a user to the power clip 34 to assist in inserting the power clip 34 into the busbar 52. Furthermore, the elastic force stored by the separator 35 may assist in separating the power clip 34 from the busbar 52, such that the user may spend less pulling force. Accordingly, the transmission mechanism 3 of the invention can assist the user in overcoming a mating force between the power clip 34 and the busbar 52.

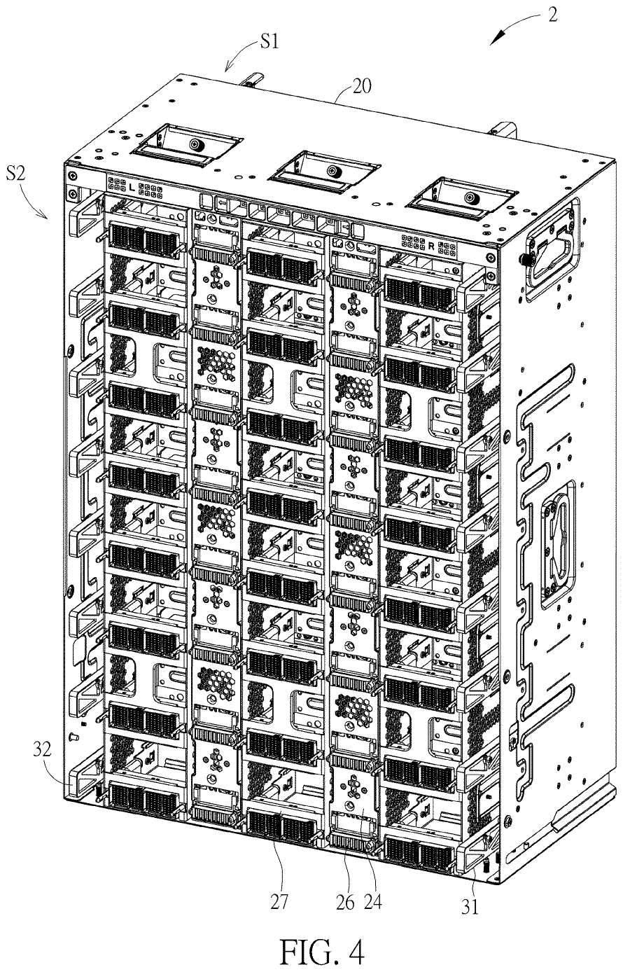

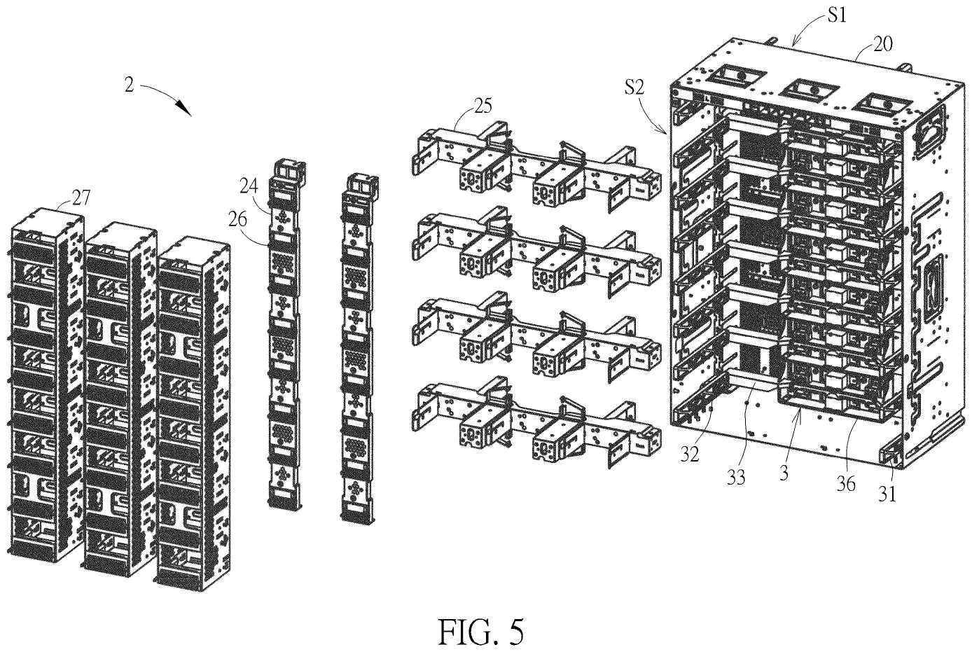

Referring to FIG. 4, which is an isometric view illustrating an adapter module 2 according to an embodiment of the invention. The adapter module 2 comprises a drawer 20, the transmission mechanism 3, a bracket 24, at least one connector 26, a cable cartridge 27 and a support structure 25 (as shown in FIG. 5). The transmission mechanism 3 is movably disposed at a rear side S1 of the drawer 20. The first sliding rod 31 and the second sliding rod 32 extend outside of a front side S2 of the drawer 20.

Referring to FIG. 5, which is an exploded view illustrating the adapter module 2 shown in FIG. 4. The bracket 24 is disposed at the front side S2 of the drawer 20 and the connector 26 is disposed on the bracket 24. The connector 26 may be connected to the corresponding power clip 34 of the transmission mechanism 3 through a cable (not shown), such that the connector 26 is electrically connected to the power clip 34. The cable cartridge 27 is also disposed at the front side S2 of the drawer 20. In this embodiment, three cable cartridges 27 and two brackets 24 may be disposed side by side at the front side S2 of the drawer 20, but the invention is not so limited. Furthermore, the support structure 25 is disposed in the drawer 20. The support structure 25 connects the drawer 20 and the bracket 24, and the cable cartridge 27 is fixed to the support structure 25. In addition to supporting the bracket 24 and the cable cartridge 27, the support structure 25 may also enhance the overall structural strength of the adapter module 2. When assembling the adapter module 2, the user may sequentially install the transmission mechanism 3, the support structure 25, the bracket 24 and the cable cartridge 27 into the drawer 20. In this embodiment, there are eight transmission mechanisms 3, four support structures 25, two brackets 24, and three cable cartridges 27. In other embodiments, the numbers of transmission mechanisms 3, brackets 24, connectors 26, cable cartridges 27 and support structures 25 may be determined according to practical applications.

Referring to FIG. 6, which is a partial inside view illustrating the adapter module 2 shown in FIG. 4. The drawer 20 may be formed with a guiding groove 28 and the cross rod 33 of the transmission mechanism 3 may comprise a guiding pin 38 (as shown in FIGS. 1 to 3). The guiding pin 38 is slidably disposed in the guiding groove 28, such that the transmission mechanism 3 may move along the guiding groove 28 with respect to the drawer 20. In practical applications, there are guiding pins 38 on two sides of the cross rod 33, and two sides of the drawer 20 are formed with guiding grooves 28 corresponding to the guiding pins 38.

The drawer 20 comprises a first guiding pin 21a and a restraining fixing member 23a. The first guiding pin 21a is fixed to the restraining fixing member 23a and penetrates the hole 36a to restrain the transmission mechanism 3 on the first guiding pin 21a. In this embodiment, the drawer 20 comprises one pair of first guiding pins 21a, 21b and one pair of restraining fixing members 23a, 23b. The first guiding pins 21a, 21b are respectively fixed to the restraining fixing members 23a, 23b and respectively correspond to the holes 36a, 36b. In other words, since the casing 36 is formed with one pair of holes 36a, 36b at two sides of one power clip 34, the first guiding pin 21a and the restraining fixing member 23a are disposed at a side of the power clip 34, and the first guiding pin 21b and the restraining fixing member 23b are disposed at another side of the power clip 34. When the transmission mechanism 3 moves with respect to the drawer 20, the first guiding pins 21a, 21b respectively penetrate the holes 36a, 36b, such that the casing 36 moves along the first guiding pins 21a, 21b to assist in aligning the power clip 34 with the busbar 52 (as shown in FIG. 8).

Furthermore, the drawer 20 may comprise a second guiding pin 22a. The second guiding pin 22a is fixed to the restraining fixing member 23a and penetrates the cover 352 of the separator 35, and the elastic member 350 of the separator 35 is sleeved on the second guiding pin 22a. In this embodiment, the drawer 20 comprises one pair of second guiding pins 22a, 22b. The second guiding pins 22a, 22b are respectively fixed to the restraining fixing members 23a, 23b and penetrate the covers 352 of the two separators 35, and the elastic members 350 of the two separators 35 are respectively sleeved on the second guiding pins 22a, 22b. When the transmission mechanism 3 is disposed in the drawer 20, two ends of the elastic member 350 of the separator 35 may abut against the cover 352 and the restraining fixing members 23a, 23b. Thus, when the transmission mechanism 3 is pushed toward the rear side S1 of the drawer 20, the elastic member 350 is compressed. When the transmission mechanism 3 is released, the compressed elastic member 350 will drive the transmission mechanism 3 to return toward the front side S2 of the drawer 20.

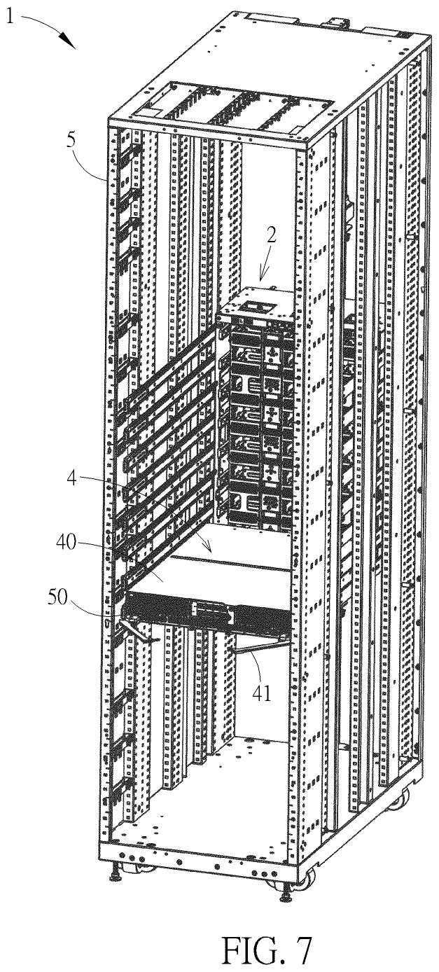

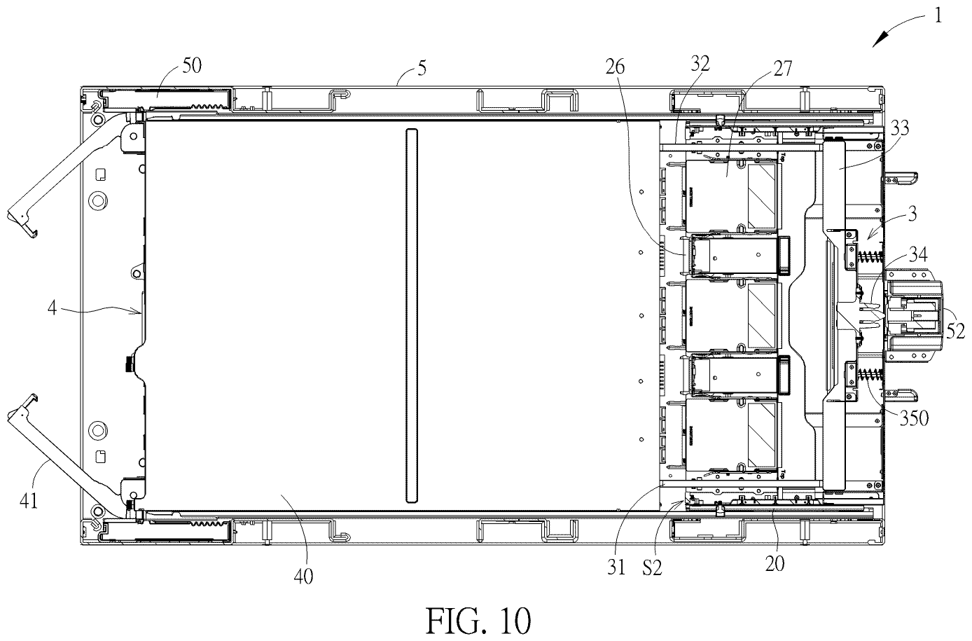

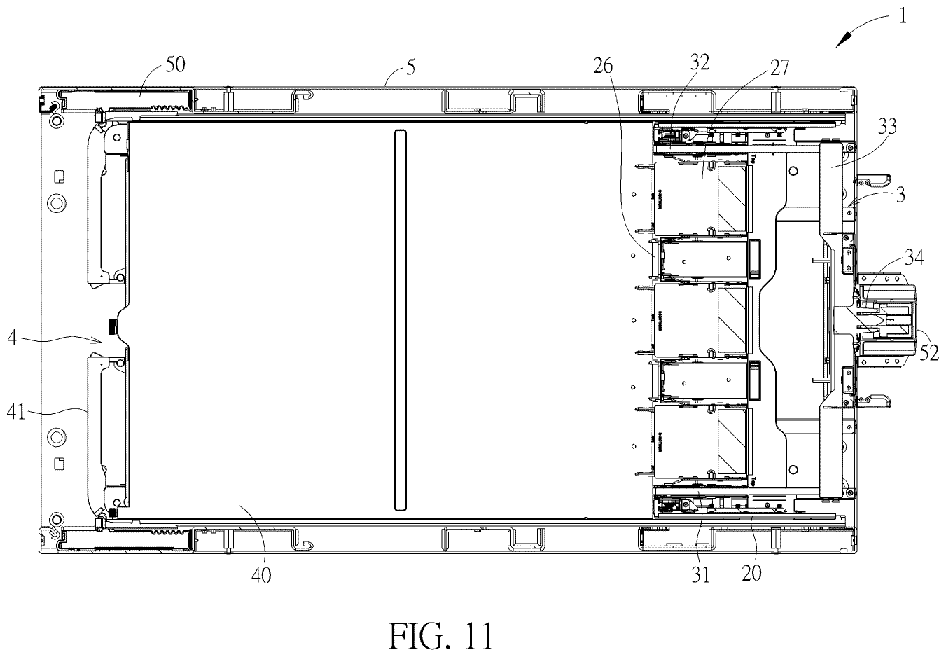

Referring to FIG. 7, which is an isometric view illustrating a data processing device 1 according to an embodiment of the invention. The data processing device 1 comprises a rack 5, the adapter module 2 and an electronic component 4. The rack 5 comprises a sliding rail 50 and a busbar 52. In this embodiment, a plurality of sliding rails 50 arranged up and down may be disposed at two sides of the rack 5 in between corresponding electronic components 4 can be installed. The electronic component 4 may be a server or other electronic components according to practical applications. The electronic component 4 may comprise a chassis 40 and at least one handle 41. The handle 41 is pivotally connected to the chassis 40 to rotate between an opened position (as shown in FIG. 10) and a closed position (as shown in FIG. 11) with respect to the chassis 40. In this embodiment, two handles 41 may be disposed at two sides of the chassis 40.

Referring to FIG. 8, which is an isometric view illustrating the data processing device 1 shown in FIG. 7 from another viewing angle. The busbar 52 is located at a rear side of the rack 5 and configured to supply power to the electronic component 4. The adapter module 2 is disposed in the rack 5 and adjacent to the busbar 52. It should be noted that the number and height of adapter module 2 may be determined according to practical applications.

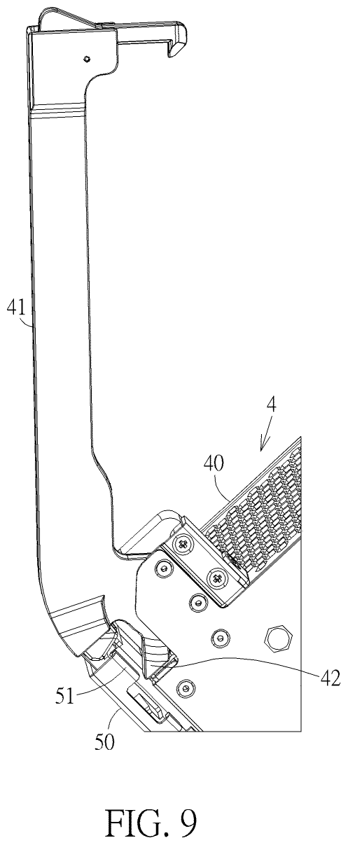

Referring to FIG. 9, which is a partial isometric view illustrating the electronic component 4, the handle 41 and the sliding rail 50 from another viewing angle. The sliding rail 50 may comprise a first engaging portion 51, and the handle 41 may comprise a second engaging portion 42. When the chassis 40 of the electronic component 4 contacts the first sliding rod 31 and the second sliding rod 32 of the transmission mechanism 3 and the handle 41 is rotating from the opened position (as shown in FIG. 10) to the closed position (as shown in FIG. 11), the second engaging portion 42 will push the first engaging portion 51 to drive the chassis 40 moving toward the adapter module 2, such that the chassis 40 pushes the first sliding rod 31 and the second sliding rod 32 to drive the transmission mechanism 3 moving toward the busbar 52.

Referring to FIG. 10, which is a top view illustrating the handle 41 of the electronic component 4 shown in FIG. 7 staying at an opened position. The first sliding rod 31 and the second sliding rod 32 of the transmission mechanism 3 extend outside of the front side S2 of the drawer 20. Thus, when the electronic component 4 is pushed into the rack 5 along the sliding rail 50, the electronic component 4 will push the first sliding rod 31 and the second sliding rod 32 to drive the transmission mechanism 3 moving toward the busbar 52, such that the electronic component 4 is connected to the connector 26 and the cable cartridge 27, and the power clip 34 is connected to the busbar 52. In other words, as long as the user pushes the electronic component 4 into the rack 5 along the sliding rail 50, the electronic component 4 will drive the transmission mechanism 3 moving toward the busbar 52, such that the power clip 34 of the transmission mechanism 3 is connected to the busbar 52. Until the electronic component 4 is pushed to the end, the electronic component 4 will be connected to the connector 26. As mentioned in the above, the connector 26 may be connected to the power clip 34 of the transmission mechanism 3 through a cable (not shown). At this moment, the electronic component 4 is electrically connected to the busbar 52 through the connector 26 and the power clip 34. Until the electronic component 4 is pushed to the end, the electronic component 4 is also connected to the cable cartridge 27. When there are a plurality of electronic components 4 installed into the rack 5, the electronic components 4 may transmit signals to each other through the cable cartridge 27.

Referring to FIG. 11, which is a top view illustrating the handle 41 of the electronic component 4 shown in FIG. 7 staying at a closed position. The user may rotate the handle 41 from the closed position to the opened position (as shown in FIG. 10) to take out the electronic component 4 from the rack 5. when the electronic component 4 moves away from the adapter module 2, the elastic member 350 of the separator 35 will drive the transmission mechanism 3 moving away from the busbar 52, such that the power clip 34 of the transmission mechanism 3 is separated from the busbar 52.

As mentioned above, when the electronic component is assembling into the rack, the electronic component can drive the power clip of the transmission mechanism being electrically connected to the busbar of the rack. When the electronic component is being taken out from the rack, the separator of the transmission mechanism will drive the power clip of the transmission mechanism being separated from the busbar of the rack. Therefore, through the arrangement of the transmission mechanism of the invention, the disassembly and assembly of the electronic component and the rack can be faster and more convenient.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transmission mechanism comprising:
a first sliding rod;
a second sliding rod parallel to the first sliding rod;
a cross rod, an end of the cross rod being connected to the first sliding rod, another end of the cross rod being connected to the second sliding rod; and
at least one power clip fixed to the cross rod.

2. The transmission mechanism of claim 1, further comprising a plurality of separators fixed to the cross rod and disposed at two sides of the at least one power clip, wherein the plurality of separators are configured to provide a force for separating the at least one power clip.

3. The transmission mechanism of claim 2, further comprising a casing fixed to the cross rod, wherein the at least one power clip and the plurality of separators are fixed to the casing.

4. The transmission mechanism of claim 3, wherein each of the plurality of separators comprises an elastic member and a cover, the cover is fixed to the casing, and an end of the elastic member abuts against the cover.

5. The transmission mechanism of claim 3, wherein two sides of the casing are formed with two engaging recesses, and the cross rod engages with the two engaging recesses.

6. The transmission mechanism of claim 1, further comprising a support frame fixed to the cross rod, wherein the support frame is configured to support the cross rod, and a stiffness of the cross rod is larger than a stiffness of the support frame.

7. The transmission mechanism of claim 1, wherein the first sliding rod and the second sliding rod extend along a first direction, the cross rod extends in a second direction, the at least one power clip is arranged along a third direction, and the first direction, the second direction and the third direction are perpendicular to each other.

8. An adapter module comprising:
a drawer;
the transmission mechanism of claim 1 movably disposed at a rear side of the drawer, the first sliding rod and the second sliding rod extending out of a front side of the drawer;
a bracket disposed at the front side of the drawer;
at least one connector disposed on the bracket, the at least one connector being connected to the at least one power clip; and
a cable cartridge disposed at the front side of the drawer.

9. The adapter module of claim 8, further comprising a support structure disposed in the drawer, wherein the support structure connects the drawer and the bracket.

10. The adapter module of claim 9, wherein the cable cartridge is fixed to the support structure.

11. The adapter module of claim 8, wherein the drawer is formed with a guiding groove, the cross rod comprises a guiding pin, and the guiding pin is disposed in the guiding groove.

12. The adapter module of claim 8, wherein the transmission mechanism further comprises a casing fixed to the cross rod and formed with a hole, the drawer comprises a first guiding pin and a restraining fixing member, and the first guiding pin is fixed to the restraining fixing member and penetrates the hole to restrain the transmission mechanism on the first guiding pin.

13. The adapter module of claim 8, wherein the transmission mechanism further comprises a plurality of separators disposed at two sides of the at least one power clip, each of the plurality of separators comprises an elastic member and a cover, the cover is fixed to the casing, two ends of the elastic member abut against the cover and the drawer, the drawer comprises a second guiding pin, the second guiding pin is fixed to the restraining fixing member and penetrates the cover, and the elastic member is sleeved on the second guiding pin.

14. A data processing device comprising:
a rack comprising a sliding rail and a busbar;
the adapter module of claim 8 disposed in the rack and adjacent to the busbar; and
an electronic component;
wherein, when the electronic component is pushed into the rack along the sliding rail, the electronic component pushes the first sliding rod and the second sliding rod to drive the transmission mechanism moving toward the busbar, such that the electronic component is connected to the at least one connector and the cable cartridge, and the at least one power clip is connected to the busbar.

15. The data processing device of claim 14, wherein the electronic component comprises a chassis and a handle, the handle is pivotally connected to the chassis to rotate between an opened position and a closed position with respect to the chassis, the sliding rail comprises a first engaging portion, and the handle comprises a second engaging portion; wherein, when the chassis of the electronic component contacts the first sliding rod and the second sliding rod and the handle rotates from the opened position to the closed position, the second engaging portion pushes the first engaging portion to drive the chassis moving toward the adapter module, such that the chassis pushes the first sliding rod and the second sliding rod to drive the transmission mechanism moving toward the busbar.

16. The data processing device of claim 14, wherein the transmission mechanism further comprises a plurality of separators disposed at two sides of the at least one power clip; wherein, when the electronic component moves away from the adapter module, the plurality of separators drive the transmission mechanism moving away from the busbar, such that the at least one power clip is separated from the busbar.
